(19) United States
(12) Patent Application Publication
(10) Pub. No.: US 2008/0304244 A1
(43) Pub. Date: Dec. 11, 2008

(54) Electrical connector having improved housing

(75) Inventor: Fu-Pin Hsieh, Tu-cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/157,656

(22) Filed: Jun. 11, 2008

(30) Foreign Application Priority Data
Jun. 11, 2007 (CN) 200720039792.9

(51) Int. Cl. H05K 7/12

(52) U.S. Cl. 361/810

(57) ABSTRACT

An electrical connector (1) is adapted for electrically connecting an electronic package (3) to a circuit board (4). The electrical connector includes a housing (5) having a number of contacts retained therein, a number of hook portions (24) rising from the housing and resisting against an upper surface of the electronic package for fastening the electronic package to the housing.

### BACKGROUND OF THE INVENTION

1. Field of the invention

The present invention relates to an electrical connector, and particularly to an electrical connector electrically connecting an electronic package such as an IC package to a circuit board.

2. Description of Related Art

An electrical connector comprises a housing having a plurality of contacts, a stiffener surrounding the housing and formed with an engaging portion, a cover rotatably mounted on the housing and having a tongue portion, and a lever engaging with the tongue portion of the cover. When an IC package is positioned on the housing, the cover is rotated to a closed position and fasten the IC package at the closed position via an engagement between the lever and the engaging portion.

The IC package could be fixed in the stiffener, under the operation of the lever and the cover. It is complicated to assemble the cover and lever onto the housing. Simultaneously, it would take great space to position the lever and the cover.

Hence, an improved electrical connector is required to overcome the above-mentioned disadvantages of the related art.

### SUMMARY OF THE INVENTION

An object of the present invention is to provide an electrical connector taking less space and easy to assemble.

To achieve the aforementioned objects, an electrical connector is adapted for electrically connecting an electronic package to a circuit board. The electrical connector includes a housing having a number of contacts retained therein, a number of hook portions rising from the housing and resisting against an upper surface of the electronic package for locking the electronic package to the housing.

The hook portions extend upwardly from the housing for fastening the IC package in the housing. It is not necessary to assemble a fastening mechanism on the housing to fasten the IC package. The housing together with the hook portions would not occupy extra space.

Other objects, advantages and novel features of the invention will become more apparent from the following detailed description of a preferred embodiment when taken in conjunction with the accompanying drawings.

### BRIEF DESCRIPTION OF THE DRAWINGS

FIG. 1 is an exploded perspective view of an electrical connector in accordance with the present invention; and

FIG. 2 is an assembled perspective view of the electrical connector as shown in FIG. 1.

### DETAILED DESCRIPTION OF THE INVENTION

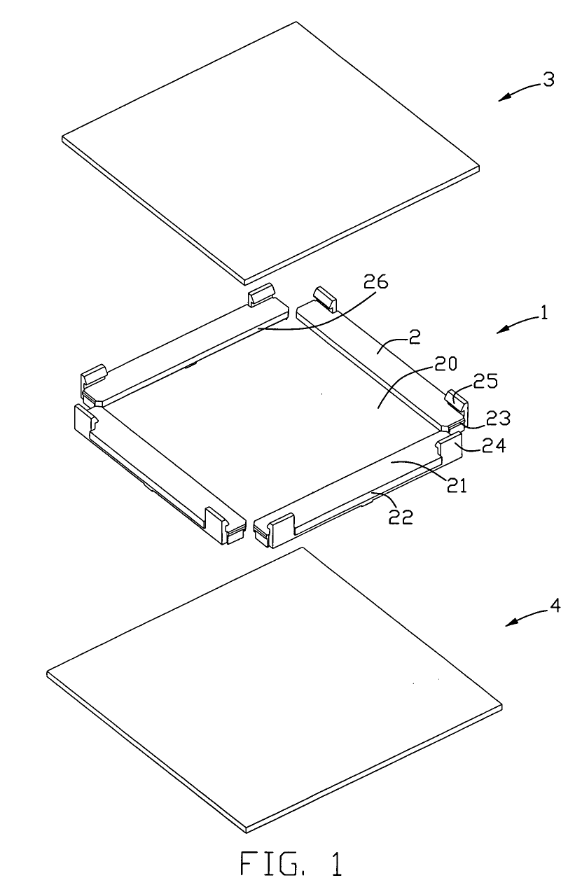

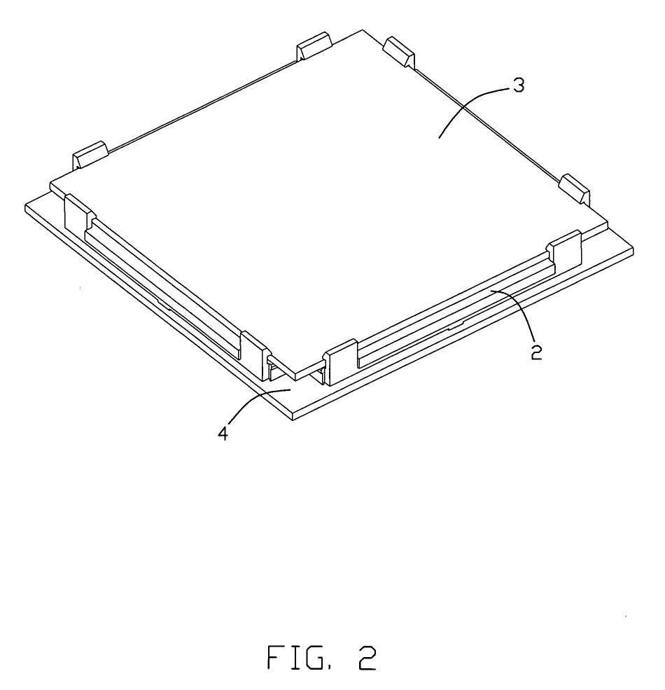

Reference will now be made to the drawing figures to describe the present invention in detail. Referring to FIGS. 1-2, an electrical connector 1 in accordance with the preferred embodiment of the present invention comprises a housing 5 electrically connecting an IC package 3 to a circuit board 4.

Referring to FIG. 1, the housing 5 comprises four separated rectangular housing units 2. Each housing unit 2 comprises a body portion 21 defining a plurality of slots (not shown) for receiving a plurality of power contacts (not shown), an outer wall 22 and an inner wall 26 extending along two opposite longitudinal edges of the body portion 21, and a pair of connecting walls 23 formed at another two opposite edges of the body portion 21. Each outer wall 22 of the housing unit 2 is symmetrically formed with a pair of hook portions 24 rising from two opposite ends thereof for engaging with the IC package 3. Each hook portion 24 has a inclined guiding face 25 formed at an top portion thereof for guiding the IC package 3.

In assembly of the electrical connector 100, the four housing units 2 are arranged as a rectangular shape to form the insulative housing 5 and soldered on the circuit board 4 firstly, with a substantially rectangular opening 20 encircled by the four housing units 2 and the inner walls 26 facing toward the opening 20. A signal connector (not shown) is received in the opening 20. The IC package 3 is guided toward the opening 20 along the guiding faces 25 and resisted against by the hook portions 24. Finally, the IC package 3 is firmly fastened to the insulative housing 5 to thereby establish a reliable electrical connection between the IC package 3 and the signal connector.

Optionally, the insulative housing 5 could be integrally formed as a rectangular flat board. The hook portions 24 could be provided at a middle portion of the four edges of the insulative housing 5 for resisting against the upper surface of the IC package 3.

The hook portions 25 extend upwardly from the housing for fastening the IC package 3 in the housing 5. It is not necessary to assemble a fastening mechanism to fasten the IC package 3. The housing 5 together with the hook portions 25 would not occupy extra space.

However, the disclosure is illustrative only, changes may be made in detail, especially in matter of shape, size, and arrangement of parts within the principles of the invention.

What is claimed is:

1. An electrical connector adapted for electrically connecting an electronic package to a circuit board, comprising:
a housing having a plurality of contacts retained therein, a plurality of hook portions rising from the housing and resisting against an upper surface of the electronic package for fastening the electronic package to the housing.

2. The electrical connector as claimed in claim 1, wherein each hook portion has an obliquely extending guiding face guidable of the electronic package.

3. The electrical connector as claimed in claim 2, wherein said housing comprises four housing units arranged as a rectangular shape and a rectangular opening encircled by the four housing units.

4. The electrical connector as claimed in claim 3, wherein said hook portions are symmetrically formed at opposite ends of an outer edge of each housing unit.

5. The electrical connector as claimed in claim 2, wherein said housing is formed as a rectangular flat board, and the hook portions extend upwardly from a middle portion of each side edge of the housing.

6. An electrical connector assembly comprising:
a plurality of insulative housing units arranged along a periphery of a receiving area; and
an IC package being configured to be essentially compliant with said receiving area and mounted upon said housing units; wherein
each of said housing units defines at least a deflectable latch under a condition that the latches of the different housing units engage different sides of said IC package, respectively.

7. The electrical connector assembly as claimed in claim 6, wherein each of said housing units is equipped with two said latches at two opposite ends of the housing units, respectively.
